(19) United States
(12) Patent Application Publication
(10) Pub. No.: US 2014/0044985 A1
(43) Pub. Date: Feb. 13, 2014

(54) PROBE FABRICATION USING COMBINED LASER AND MICRO-FABRICATION TECHNOLOGIES

(71) Applicant: FormFactor, Inc., Livermore, CA (US)

(72) Inventor: January Kister, Portola Valley, CA (US)

(73) Assignee: FormFactor, Inc., Livermore, CA (US)

(21) Appl. No.: 13/963,402

(22) Filed: Aug. 9, 2013

Related U.S. Application Data
(60) Provisional application No. 61/681,566, filed on Aug. 9, 2012.

(51) Int. Cl. G01R 3/00; B23K 26/38

(52) U.S. Cl. CPC G01R 3/00; B23K 26/38
USPC 428/601; 219/121.72

(57) ABSTRACT

A method of making a probe (and the resulting probe) comprising providing a metal foil, creating a tip on an edge of the foil, and laser cutting a body of the probe from the foil with one or more tips at an end of the body.

### CROSS-REFERENCE TO RELATED APPLICATIONS

This application claims priority to and the benefit of the filing of U.S. Provisional Patent Application Ser. No. 61/681,566, entitled “Probe Fabrication Using Combined Laser and Micro-Fabrication Technology”, filed on Aug. 9, 2012, and the specification and claims thereof are incorporated herein by reference.

### STATEMENT REGARDING FEDERALLY SPONSORED RESEARCH OR DEVELOPMENT

Not Applicable.

### INCORPORATION BY REFERENCE OF MATERIAL SUBMITTED ON A COMPACT DISC

Not Applicable.

### COPYRIGHTED MATERIAL

Not Applicable.

### BACKGROUND OF THE INVENTION

1. Field of the Invention (Technical Field)

The present invention relates to probe fabrication methods and probe products thus manufactured.

2. Description of Related Art

Laser machining has been employed to fabricate vertical probes for probing integrated circuits. However, it has been found that this fabrication approach may not provide sufficient control over fine details of probe shape. In one example, probe designs where the probe tip has a reduced-width section (which can be referred to as a skate) were laser fabricated. The resulting variability of skate width was about 3 μm, which leads to a significant reduction of probe yield.

### BRIEF SUMMARY OF THE INVENTION

The present invention is of a method of making a probe (and the resulting probe), comprising: providing a metal foil; creating a tip on an edge of the foil; and laser cutting a body of the probe from the foil with one or more tips at an end of the body. In the preferred embodiment, creating comprises one or more of laser cutting, plating, depositing, and sputtering material. For plating, depositing, or sputtering, the material can be layered, and preferably comprises Rhodium or Palladium. Etching spring material may be done prior to the plating, depositing, and/or sputtering, and preferably the spring material comprises BeCu. Laser cutting is preferably performed by one or more picosecond lasers. The method can additionally comprise creating a distal end of the probe proximate an edge of the metal foil opposite the edge having the tip, preferably by one or more of laser cutting, plating, depositing, and sputtering material. The distal end can be etched with spring material prior to the plating, depositing, and/or sputtering of material.

Further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention. In the drawings:

FIG. 1 is a perspective view of metal foil the beginning of the method of the invention;

FIG. 2 is a perspective view of same after creation of a tip by etching/plating;

FIG. 3 is a top detail view of the tip; and

FIG. 4 is a perspective view of the foil after laser cutting of the probe body.

### DETAILED DESCRIPTION OF THE INVENTION

With the present invention, the problems cited above are addressed by employing micro-fabrication technology (e.g., as used in microelectronics fabrication, micro-electro-mechanical systems (MEMS) fabrication, etc.) to fabricate critical parts of the probes (e.g., probe tips and/or probe distal ends). Here distal refers to the end of the probe that is opposite the tip. Such micro-fabrication technology includes, but is not limited to etching (single or dual sided), and layer build up (e.g., by deposition, plating, sputtering etc.). For example, the probe tip can be coating with a contact material (e.g., rhodium, palladium etc.) after its mechanical features (e.g., the skate) are defined. After the fine features of probes have been formed with micro-fabrication technology, the remaining parts of the probe shape can be defined via laser machining. This approach provides the advantages of both micro-fabrication (good control of small feature sizes) and laser machining (flexibility, ability to handle larger structures than micro-fabrication).

The preferred method of the present invention starts with a metal foil that has alignment features for future processing. The tip feature can be created using two-sided etching of spring material (e.g., BeCu) followed by plating the tip with desirable contactor material (e.g., Rh, Pd, etc.). Another option is to start with the tip feature and the foil created through MEMS/Multi-layer metal plating/deposition (including sputtering). This allows for accurate tip feature creation coated with such metals as Rhodium, Palladium. etc. The same can be applied to creation of the distal end of the probe. The body of the probe is preferably laser cut after the tip/distal end are made. Picosecond laser cutting is preferred.

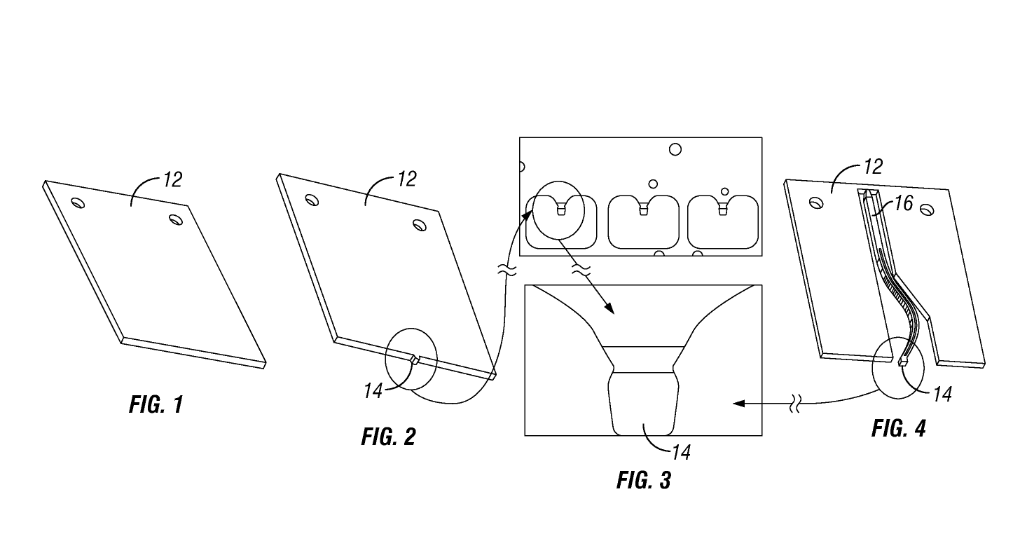

Referring to the figures, FIG. 1 illustrates the starting metal foil 12. FIG. 2 shows the foil after tip 14 creation by etching/plating. FIG. 3 shows detail of the tip and a preferred shape thereof. FIG. 4 shows the foil after laser cutting of the probe body 16, with the tip intact thereon. FIG. 4 shows a probe body with an extended portion comprising multiple discrete probe sections that are then joined at the tip, although a traditional single-section extended portion can also be made according to the invention. Furthermore, the probe can be made such that more than one tip is created at the end of the probe. Additionally, the tip or tips (as well as the distal end) may also be formed by laser cutting.

Note that in the specification and claims, “about” or “approximately” means within twenty percent (20%) of the numerical amount cited.

Although the invention has been described in detail with particular reference to these preferred embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference.

What is claimed is:

1. A method of making a probe, the method comprising the steps of:
providing a metal foil;
creating a tip on an edge of the foil; and
laser cutting a body of the probe from the foil with one or more tips at an end of the body.

2. The method of claim 1 wherein the creating step comprises one or more of laser cutting, plating, depositing, and sputtering material.

3. The method of claim 2 wherein the creating step comprises layering the material by one or more of plating, depositing, and sputtering.

4. The method of claim 3 wherein the material comprises Rhodium or Palladium.

5. The method of claim 3 wherein the creating step additionally comprises etching spring material prior to the one or more of plating, depositing, and sputtering material.

6. The method of claim 5 wherein the spring material comprises BeCu.

7. The method of claim 1 wherein the laser cutting employs one or more picosecond lasers.

8. The method of claim 1 additionally comprising creating a distal end of the probe proximate an edge of the metal foil opposite the edge having the tip.

9. The method of claim 8 wherein creating the distal end comprises one or more of laser cutting, plating, depositing, and sputtering material.

10. The method of claim 9 wherein creating the distal end additionally comprises etching spring material prior to one or more of plating, depositing, and sputtering material.

11. A probe made via the steps of:
providing a metal foil;
creating a tip on an edge of the foil; and
laser cutting a body of the probe from the foil with one or more tips at an end of the body.

12. The probe of claim 11 wherein the creating step comprises one or more of laser cutting, plating, depositing, and sputtering material.

13. The probe of claim 12 wherein the creating step comprises layering the material by one or more of plating, depositing, and sputtering.

14. The probe of claim 13 wherein the material comprises Rhodium or Palladium.

15. The probe of claim 13 wherein the creating step additionally comprises etching spring material prior to the one or more of plating, depositing, and sputtering material.

16. The probe of claim 15 wherein the spring material comprises BeCu.

17. The probe of claim 11 wherein the laser cutting employs one or more picosecond lasers.

18. The probe of claim 11 additionally comprising creating a distal end of the probe proximate an edge of the metal foil opposite the edge having the tip.

19. The probe of claim 18 wherein creating the distal end comprises one or more of laser cutting, plating, depositing, and sputtering material.

20. The probe of claim 19 wherein creating the distal end additionally comprises etching spring material prior to one or more of plating, depositing, and sputtering material.
